(19) United States
(12) Patent Application Publication
(10) Pub. No.: US 2009/0103262 A1
(43) Pub. Date: Apr. 23, 2009

(54) ELECTRONIC APPARATUS

(75) Inventor: Yukihiko Hata, Hamura-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/199,528

(22) Filed: Aug. 27, 2008

(30) Foreign Application Priority Data
Oct. 19, 2007 (JP) 2007-272985

(51) Int. Cl. H05K 7/20

(52) U.S. Cl. 361/689

(57) ABSTRACT

According to one embodiment, an electronic apparatus is provided with first and second heating elements mounted on a circuit board. The first heat pipe includes a first end portion thermally connected to the first heating element and a second end portion thermally connected to a heat radiating section. The second heat pipe includes a first end portion thermally connected to the second heating element, a second end portion thermally connected to the heat radiating section, and a middle portion opposed to the first heating element. A heat conductive member has flexibility and is provided between the middle portion of the second heat pipe and the first heating element so as to thermally connect the middle portion of the second heat pipe to the first heating element.

### CROSS-REFERENCE TO RELATED APPLICATIONS

This application is based upon and claims the benefit of priority from Japanese Patent Application No. 2007-272985, filed Oct. 19, 2007, the entire contents of which are incorporated herein by reference.

### BACKGROUND

1. Field

One embodiment of the invention relates to an electronic apparatus provided with a heat radiating structure.

2. Description of the Related Art

An electronic apparatus, such as a portable computer, is furnished with a plurality of heating elements, for example. An electronic apparatus provided with a heat radiating structure for cooling a plurality of heating elements is disclosed in Jpn. Pat. Appln. KOKAI Publication No. 2007-34699. This electronic apparatus includes a radiator opposed to a cooling fan, a first heat pipe that transports heat from a first heating element to the radiator, and a second heat pipe that transports heat from the second heating element to the radiator. The first and second heat pipes are provided individually on the opposite sides of the cooling fan. In this electronic apparatus, the mounting position of the cooling fan is restricted, and the degree of freedom of the design of a circuit board is not high.

Disclosed in Jpn. Pat. Appln. KOKAI Publication No. 2006-310740 is an electronic apparatus in which cooling of a plurality of heating elements may be facilitated and the cooling fan may be mounted with a high degree of freedom. This electronic apparatus is constructed substantially in the same manner as the one described in Jpn. Pat. Appln, KOKAI Publication No. 2007-34699, in which first and second heat pipes are located together on one side of the cooling fan.

If a plurality of heat pipes are located together on one side of the cooling fan, as in the electronic apparatus described in Jpn. Pat. Appln. KOKAI Publication No. 2006-310740, the heat pipes tend to be long. If the heat pipes are long, it is difficult to realize a high cooling performance.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary sectional view of the portable computer shown in FIG. 1;

FIG. 3 is an exemplary sectional view of a first heating element taken along line F3-F3 of FIG. 2;

FIG. 4 is an exemplary sectional view of a second heating element taken along line F4-F4 of FIG. 2;

FIG. 5 is an exemplary sectional view showing a modification of the portable computer shown in FIG. 1;

FIG. 6 is an exemplary sectional view of a portable computer according to a second embodiment of the invention;

FIG. 7 is an exemplary sectional view of a first heating element taken along line F7-F7 of FIG. 6;

FIG. 8 is an exemplary sectional view of a second heating element taken along line F8-F8 of FIG. 2;

FIG. 9 is an exemplary sectional view of a portable computer according to a third embodiment of the invention;

FIG. 10 is an exemplary sectional view of a second heating element taken along line F10-F10 of FIG. 9; and

FIG. 11 is an exemplary sectional view of a portable computer according to a fourth embodiment of the invention.

### DETAILED DESCRIPTION

Various embodiments according to the invention will be described hereinafter with reference to the accompanying drawings. In general, according to one embodiment of the invention, an electronic apparatus is provided with a housing, a circuit board contained in the housing, a heat radiating section provided in the housing, a first heating element mounted on the circuit board, a second heating element mounted on the circuit board, a first heat pipe, a second heat pipe, and a heat conductive member. The first heat pipe includes a first end portion thermally connected to the first heating element and a second end portion thermally connected to the heat radiating section. The second heat pipe includes a first end portion thermally connected to the second heating element, a second end portion thermally connected to the heat radiating section, and a middle portion opposed to the first heating element. The heat conductive member has flexibility and is provided between the middle portion of the second heat pipe and the first heating element so as to thermally connect the middle portion of the second heat pipe to the first heating element.

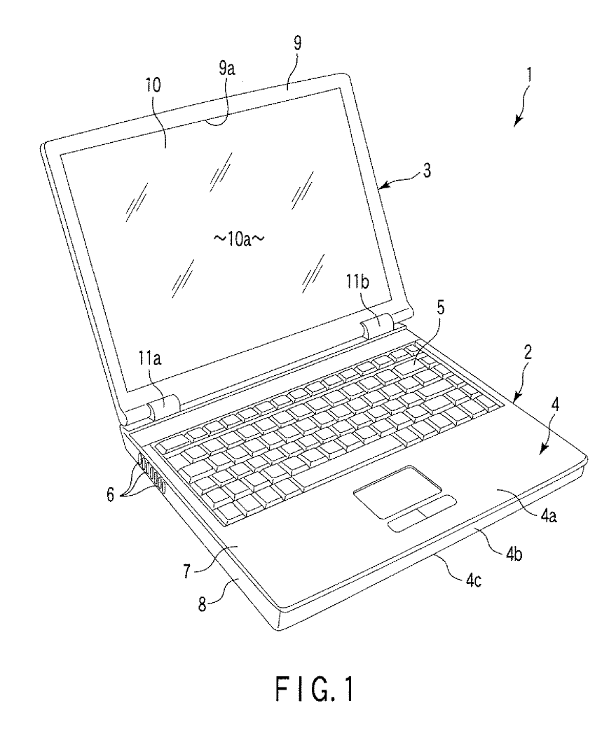

An embodiment of the present invention applied to a portable computer will now be described with reference to the accompanying drawings. FIGS. 1 to 4 show a portable computer 1 as an electronic apparatus according to a first embodiment of the invention. FIG. 1 shows an outline of the portable computer 1. As shown in FIG. 1, the portable computer 1 is provided with a body 2 and a display unit 3. The body 2 includes a box-like housing 4.

The housing 4 includes a top wall 4a, a peripheral wall, 4b, and a bottom wall 4c. The top wall 4a supports a keyboard 5. Exhaust holes 6 are provided in the peripheral wall 4b. The housing 4 is provided with a housing cover 7 including the top wall 4a and a housing base 8 including the bottom wall 4c. The housing cover 7 is combined with the housing base B from above so that a storage space is defined between the cover 7 and the base 8.

As shown in FIG. 1, the display unit 3 is provided with a display housing 9 and a display device 10 contained in the display housing. The display device 10 includes a display screen 10a. The display screen 10a is exposed to the outside of the display housing 9 through an opening part 9a in a front surface of the housing 9.

The display unit 3 is supported on the rear end portion of the housing 4 by a pair of hinge parts 11a and 11b. Thus, the display unit 3 is swingable between a closed position in which it is level so as to cover the top wall 4a from above, and an open position in which it is raised so that the top wall 4a is exposed.

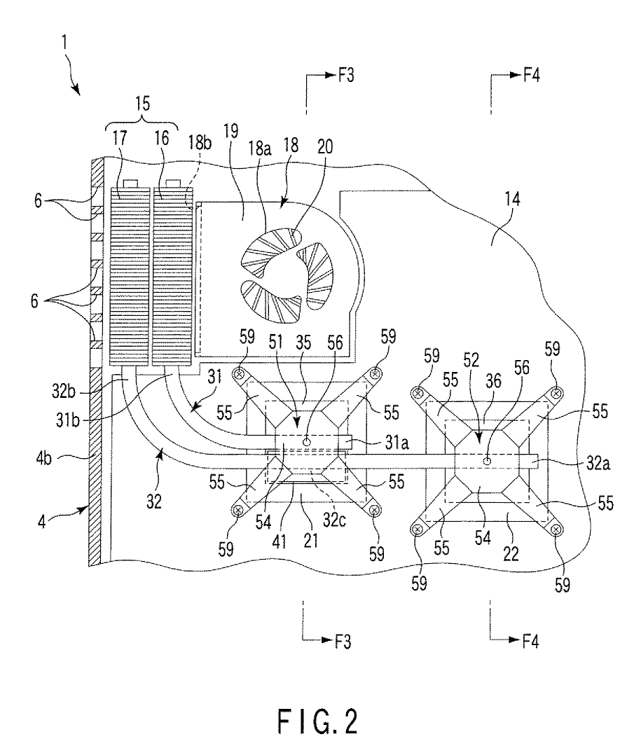

FIG. 2 shows the interior of the housing 4. As shown in FIG. 2, a circuit board 14 is contained in the housing 4. Further, a heat radiating section 15 is provided in the housing 4. The radiating section 15 is opposed to the exhaust holes 6 of the peripheral wall 4b. The radiating section 15 includes first and second radiating members 16 and 17 that are independent of each other. As the radiating members 16 and 17 are independent of each other, they are not coupled to each other, which means that the position and inclination of one cannot be influenced by those of the other. For example, the radiating members 16 and 17 are radiators that each include a plurality of fins.

As shown in FIG. 2, a cooling fan 18 is provided in the housing 4. The fan 18 is opposed to the radiating section 15. The fan 18 includes, for example, a fan case 19 and an impeller 20 that is rotated in the case 19. The fan case 19 is provided with intake ports 18a that open into the case 19 and discharge ports 18b that are opposed to the radiating section 15.

The cooling fan 18 draws air from the housing 4 through the intake ports 18a and discharges the drawn air toward the radiating section 15 through the discharge ports 18b. The first and second radiating members 16 and 17 are arranged back and forth in the direction of the air discharged by the cooling fan 18. The single cooling fan 18 cools the two radiating members 16 and 17 together.

As shown in FIG. 2, first and second heating elements 21 and 22 are mounted on the circuit board 14. The heating elements 21 and 22 are electronic components that individually generate heat when activated. Specific examples of these elements are a CPU, graphic chip, North bridge (trademark), memory, etc. However, the first and second heating elements 21 and 22 are not limited to those examples, and may be any components that require heat radiation.

As shown in FIG. 2, the second heating element 22 is located farther from the radiating section 15 than the first heating element 21 is. The first heating element 21 is situated, for example, between the second heating element 22 and the radiating section 15.

For example, the energy consumption of the second heating element 22 is larger than that of the first heating element 21. More specifically, the second heating element 22 generates more heat than the first heating element 21, so that the former is more easily heated to a high temperature than the latter.

For example, moreover, the upper limit of the specification temperature of the first heating element 21 is higher than that of the second heating element 22. The specification temperature (i.e., spec temperature) is a temperature range in which the operation of the component concerned is secured.

As shown in FIG. 2, first and second heat pipes 31 and 32 are provided in the housing 4. They are located together on one side of the cooling fan 18. Thus, the mounting position of the cooling fan 18 may not be easily restricted, so that the circuit board 14 may be designed with a higher degree of freedom.

Each of the first and second heat pipes 31 and 32 includes a container having a hollow space therein, a wick provided in the container, and a working fluid sealed in the container. The heat pipes transport heat by utilizing the latent heat of vaporization and condensation.

Specifically, each heat pipe includes a heat receiving portion thermally connected to each corresponding heating element and a heat radiating portion thermally connected to the radiating section. The working fluid absorbs heat from the heat receiving portion and evaporates into a gas, which moves to the radiating portion. The working fluid releases heat at the radiating portion and condenses into a liquid, which flows back to the heat receiving portion. Thus, the heat pipes transport heat from the heating elements to the radiating section.

As shown in FIG. 2, the first heat pipe 31 extends from the first heating element 21 to the radiating section 15. It includes a first end portion 31a and a second end portion 31b. The first end portion 31a is a heat receiving portion that is thermally connected to the first heating element 21, The second end portion 31b is a heat radiating portion that is thermally connected to the first radiating member 16. The first heat pipe 31 receives heat from the first heating element 21 and transports the received heat to the first radiating member 16.

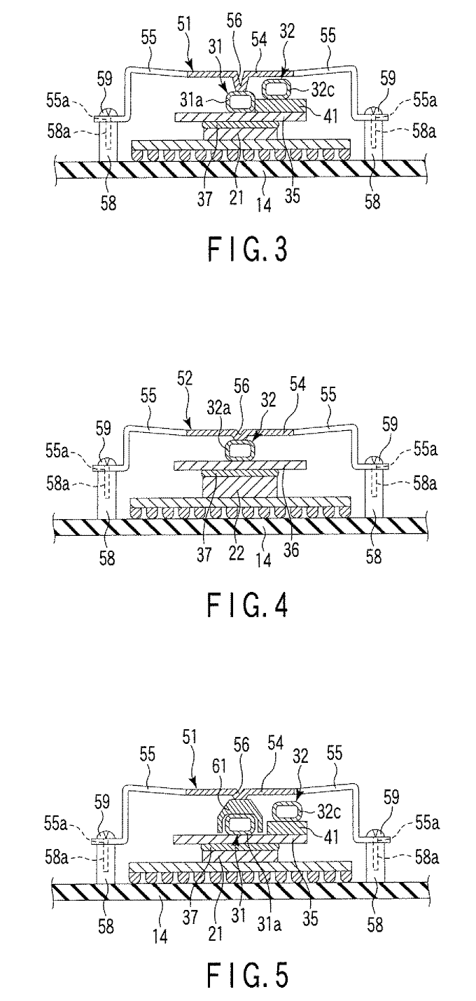

As shown in FIG. 3, a first heat receiving member 35 is provided between the first heat pipe 31 and the first heating element 21. An example of the first heat receiving member 35 is a heat receiving plate. The first heat receiving member 35 is opposed and thermally connected to the first heating element 21. For example, a heat conductive grease 37 is spread between the first heat receiving member 35 and the first heating element 21. The grease 37 serves to enhance the thermal connection between the first heat receiving member 35 and the first heating element 21.

The first end portion 31a of the first heat pipe 31 is fixed to the first heat receiving member 35 by, for example, soldering. Thus, the first end portion 31a is thermally connected to the first heat receiving member 35.

As shown in FIG. 2, on the other hand, the second heat pipe 32 extends from the second heating element 22 to the radiating section 15 through a region where it is opposed to the first heating element 21. The second heat pipe 32 is longer than the first heat pipe 31. The second heat pipe 32 includes a first end portion 32a, a second end portion 32b, and a middle portion 32c that is provided between the first and second end portions 32a and 32b and is opposed to the first heating element 21.

The first end portion 32a is a first heat receiving portion that is thermally connected to the second heating element 22. The second end portion 32b is a heat radiating portion that is thermally connected to the second radiating member 17. The second heat pipe 32 receives heat from the second heating element 22 and transports the received heat to the second radiating member 17.

As shown in FIG. 4, a second heat receiving member 36 is provided between the second heat pipe 32 and the second heating element 22. An example of the second heat receiving member 36 is a heat receiving plate. The second heat receiving member 36 is opposed and thermally connected to the second heating element 22. For example, the heat conductive grease 37 is spread between the second heat receiving member 36 and the second heating element 22. The grease 37 serves to enhance the thermal connection between the second heat receiving member 36 and the second heating element 22.

The first end portion 32a of the second heat pipe 32 is fixed to the second heat receiving member 36 by, for example, soldering. Thus, the first end portion 32a is thermally connected to the second heat receiving member 36.

As shown in FIG. 3, a heat conductive member 41 is provided between the middle portion 32c of the second heat pipe 32 and the first heat receiving member 35. The heat conductive member 41 thermally connects the middle portion 32c of the second heat pipe 32 to the first heat receiving member 35. Thus, the middle portion 32c of the second heat pipe 32 is thermally connected to the first heating element 21 through the heat conductive member 41 and the first heat receiving member 35. Further, the middle portion 32c of the second heat pipe 32 is thermally connected to the first end portion 31a of the first heat pipe 31 through the heat conductive member 41 and the first heat receiving member 35.

The heat conductive member 41 has flexibility. According to the present invention, this means that the member 41 is deformable according to the size of a gap between the second heat pipe 32 and the first heat receiving member 35, for example. If the heat conductive member 41 has flexibility, from another point of view, then it is expected to be able to absorb a variation in the size of the gap between the second heat pipe 32 and the first heat receiving member 35 that is caused by the tolerance of each component, for example.

An example of the heat conductive member 41 is a heat conductive sheet. This heat conductive sheet is formed mainly of, for example, a synthetic resin, with sufficient flexibility to be fitted to the component shape, for example. If the first heat receiving member 35 is not provided, “the gap between the second heat pipe 32 and the first heat receiving member 35” should be replaced with “a gap between the second heat pipe 32 and the first heating element 21.”

As shown in FIG. 3, the first end portion 31a of the first heat pipe 31 is thermally connected to a central portion of the first heat receiving member 35. The middle portion 32c of the second heat pipe 32 is thermally connected through the heat conductive member 41 to a peripheral portion that is off the central portion of the first heat receiving member 35.

As shown in FIG. 2, the circuit board 14 is fitted with first and second pressing members 51 and 52 that fix the first and second heat pipes 31 and 32. As shown in FIGS. 2 and 3, the first pressing member 51 includes a body portion 54 and a plurality of, e.g., four, leg portions 55.

The body portion 54 is shaped, for example, like a plate and opposed to the first end portion 31a of the first heat pipe 31. The body portion 54 is provided with a protrusion 56 that projects toward the first heat pipe 31. The leg portions 55 extend outward from the peripheral edge of the body portion 54 and are bent toward the circuit board 14. The distal end portion of each leg portion 55 is provided with a screw insertion hole 55a. The body portion 54 and the leg portions 55 jointly form a leaf spring structure.

As shown in FIG. 3, a plurality of studs 58 are set up on the circuit board 14 so as to correspond individually to the leg portions 55 of the first pressing member 51. Each stud 58 is provided with an internally threaded fixing hole 58a. When screws 59 are threaded into the fixing holes 58a of the studs 58 through the screw insertion holes 55a of the leg portions 55, individually, the first pressing member 51 is fixed to the circuit board 14. The first pressing member 51 functions as a leaf spring, and the protrusion 56 presses the first end portion 31a of the first heat pipe 31 toward the first heating element 21. The first pressing member 51 has a gap between the second heat pipe 32. That is, the first pressing member 51 is not in contact with the second heat pipe 32.

The second pressing member 52, like the first pressing member 51, for example, includes a body portion 54 and a plurality of, e.g., four, leg portions 55. The body portion 54 is shaped, for example, like a plate and opposed to the first end portion 32a of the second heat pipe 32. The body portion 54 is provided with a protrusion 56 that projects toward the second heat pipe 32. The body portion 54 and the leg portions 55 jointly form a leaf spring structure.

As shown in FIG. 4, a plurality of studs 58 are set up on the circuit board 14 so as to correspond individually to the leg portions 55 of the second pressing member 52. When screws 59 are threaded into fixing holes 58a of the studs 58 through screw insertion holes 55a of the leg portions 55, individually, the second pressing member 52 is fixed to the circuit board 14. The second pressing member 52 functions as a leaf spring, and the protrusion 56 presses the first end portion 32a of the second heat pipe 32 toward the second heating element 22. The second pressing member 52 further presses the middle portion 32c of the second heat pipe 32 toward the heat conductive member 41 by pressing the first end portion 32a of the second heat pipe 32 toward the second heating element 22.

The following is a description of a function of the portable computer 1.

When the portable computer 1 is in operation, the first and second heating elements 21 and 22 individually generate heat. A part of the heat generated by the second heating element 22 is received through the second heat receiving member 36 by the first end portion 32a of the second heat pipe 32 and transported to the radiating section 15 by the pipe 32.

On the other hands a part of heat generated by the first heating element 21 is received through the first heat receiving member 35 by the first end portion 31a of the first heat pipe 31 and transported to the radiating section 15 by the pipe 31. Further, another part of the heat from the first heating element 21 is received through the first heat receiving member 35 and the heat conductive member 41 by the middle portion 32c of the second heat pipe 32 and transported to the radiating section 15 by the pipe 32.

The portable computer 1 has another function. A heat pipe has a characteristic such that its heat transport capacity sometimes may be reduced if it is tilted at a predetermined angle or more. In this case, the heat transport capacity of the second heat pipe 32, which is longer than the first heat pipe 31, tends to be lower than that of the first heat pipe 31.

In the portable computer 1 according to the present embodiment, the first end portion 31a of the first heat pipe 31 is thermally connected to the second heat pipe 32 by the heat conductive member 41. If the heat transport capacity of the second heat pipe 32 is reduced, therefore, the first heat pipe 31 takes a part of heat from the second heat pipe 32 and transports a part of heat from the second heating element 22 to the radiating section 15.

The portable computer 1 constructed in this manner may provide a high cooling performance. Since the heat conductive member 41 is provided between the middle portion 32c of the second heat pipe 32 and the first heating element 21, heat from the first heating element 21 may be transported by the two heat pipes 31 and 32, so that cooling of the first heating element 21 may be facilitated. If the heat transport capacity of the second heat pipe 32 is reduced when the portable computer 1 is used in an inclined position, for example, the reduced heat transport capacity may be partially compensated for by the agency of the first heat pipe 31. In other words, an angle-dependent reduction in the heat transport capacity may be eased. Thus, the cooling of the second heating element 22 may be made easier than in the case where the heat conductive member 41 is not provided.

If the heat conductive member 41 has flexibility, it may absorb a variation in the size of the gap between the second heat pipe 32 and the first heat receiving member 35 that is caused by the tolerance of each component, thereby ensuring a stronger thermal connection between the second heat pipe 32 and the first heating element 21.

If the second heat pipe 32 extends through the region where it is opposed to the first heating element 21, it may be thermally connected to the first heating element 21 with ease. If the middle portion 32c is pressed toward the heat conductive member 41 by the second pressing member 52 that presses the first end portion 32a of the second heat pipe 32, the first end portion 32a can less easily lift above the second heating element 22 than in the case where a member for pressing the middle portion 32c is provided separately. In this case, therefore, the first end portion 32a may be more strongly thermally connected to the second heating element 22. If the heat conductive member 41 has flexibility, moreover, the middle portion 32c may be strongly thermally connected to the heat conductive member 41 by the pressing member 52 that presses the first end portion 32a of the second heat pipe 32.

If there is a gap between the second heat pipe 32 and the pressing member 51 that presses the first end portion 31a of the first heat pipe 31 toward the first heating element 21, the second heat pipe 32 dose not easily lift above the second heating element 22, so that it may be more strongly thermally connected to the second heating element 22.

The first and second heat receiving members 35 and 36 facilitate the areas of thermal connection between the heating elements 21 and 22 and the heat pipes 31 and 32 to be secured. If the first and second radiating members 16 and 17 are independent of each other, the first and second heat pipes 31 and 32 may be mounted in accordance with the component tolerances of the first and second heating elements 21 and 22. If the heating elements 21 and 22 and the heat receiving members 35 and 36 are thermally connected to one another by the heat conductive grease 37, they may be more strongly connected than in the case where a heat conductive sheet is used, for example.

If the first end portion 31a of the first heat pipe 31 is thermally connected to the central portion of the first heat receiving member 35, and if the middle portion 32c of the second heat pipe 32 is thermally connected to the portion off the central portion of the first heat receiving member 35, the first heat pipe 31 that is intended mainly to facilitate heat radiation of the first heating element 21 may be made to achieve its capacity.

If the energy consumption of the second heating element 22 is higher than that of the first heating element 21, heat may not readily flow back, so that the operation of the second heat pipe 32 is easily stabilized. In other words, the first heating element 21 may accept a part of heat from the second heating element 22, as well as heat generated by itself. If the upper limit of the specification temperature of the first heating element 21 is higher than that of the second heating element 22, the reliability of the portable computer 1 is improved.

One modification of the present embodiment will now be described with reference to FIG. 5. A portable computer 1 shown in FIG. 5 is provided with a padding member 61 between the first end portion 31a of the first heat pipe 31 and the first pressing member 51. The mounting height of the padding member 61 on the first heat pipe 31 above the surface of the circuit board 14 is greater than that of the second heat pipe 32. By means of the padding member 61, the first pressing member 51 may be securely prevented from contacting the second heat pipe 32. This modification is also applicable to each of the following embodiments.

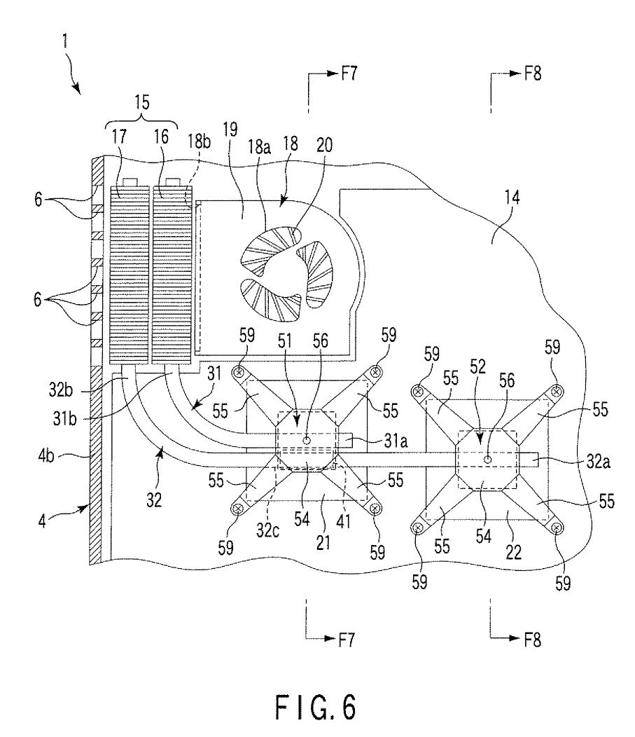

A portable computer 1 as an electronic apparatus according to a second embodiment of the invention will now be described with reference to FIGS. 6 to 8. Like reference numbers are used to designate structures of the portable computers of the first and second embodiments having the same or similar functions, and a description of those structures is omitted.

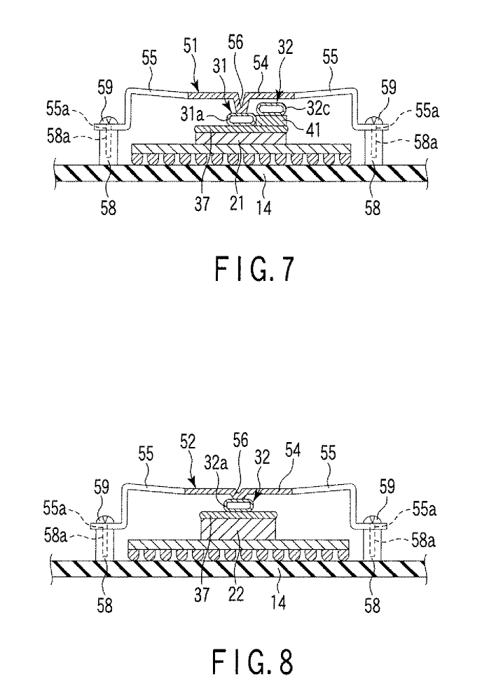

As shown in FIG. 7, the portable computer 1 according to the present embodiment is not provided with any heat receiving members. A first end portion 31a of a first heat pipe 31 is thermally connected to a first heating element 21 through, for example, a heat conductive grease 37. A middle portion 32c of a second heat pipe 32 is thermally connected to the first heating element 21 through a heat conductive member 41 and, for example, the heat conductive grease 37. As shown in FIG. 8, a first end portion 32a of the second heat pipe 32 is thermally connected to a second heating element 22 through, for example, a heat conductive grease 37. The remaining configurations of the portable computer 1 other than those described above are the same as those of the first embodiment.

Also with this arrangement, heat from the first heating element 21 may be transported by the two heat pipes 31 and 32, and the heat transport capacity of the pipes may not be easily reduced even when the portable computer 1 is tilted, for example. Thus, a high cooling performance may be realized. If the heat pipes 31 and 32 are formed flat so that a large surface area is in contact with the heating elements 21 and 22, for example, a higher cooling performance may be realized.

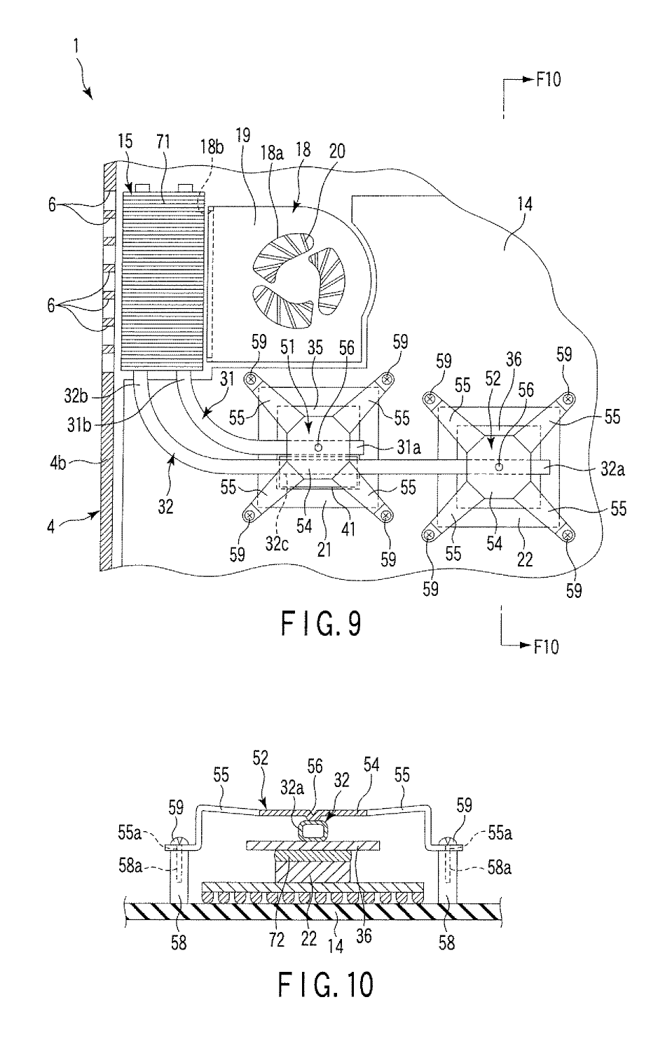

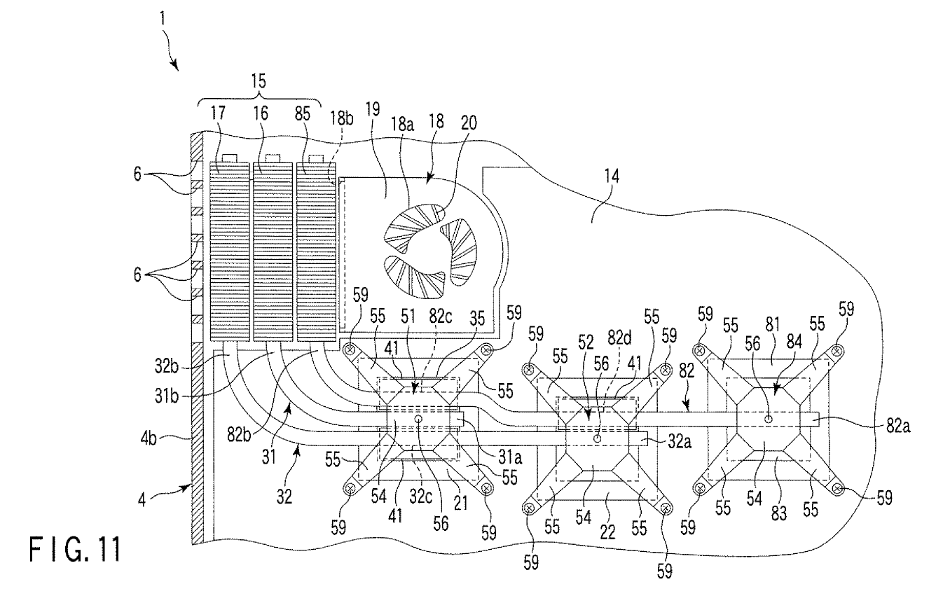

A portable computer 1 as an electronic apparatus according to a third embodiment of the invention will now be described with reference to FIGS. 9 and 10. Like reference numbers are used to designate structures of the portable computers of the first and third embodiments having the same or similar functions, and a description of those structures is omitted.

As shown in FIG. 9, a heat radiating section 15 according to the present embodiment is formed of one radiating member 71. An example of the radiating member 71 is a radiator that includes a plurality of fins. A second end portion 31b of a first heat pipe 31 is connected to the radiating member 71. A second end portion 32b of a second heat pipe 32 is connected to the radiating member 71. As shown in FIG. 10, a heat conductive sheet 72 is interposed between a second heating element 22 and a second heat receiving member 36. The remaining configurations of the portable computer 1 other than those described above are the same as those of the first embodiment.

Also with this arrangement, heat from a first heating element 21 may be transported by the two heat pipes 31 and 32, and the heat transport capacity of the pipes may not be easily reduced even when the portable computer 1 is tilted, for example. Thus, a high cooling performance may be realized. If the flexible heat conductive sheet 72 is interposed between the second heating element 22 and the second heat receiving member 36 and/or between the first heating element 21 and a first heat receiving member 35, the component tolerances of the first and second heating elements 21 and 22 may be absorbed. Thus, the heat pipes 31 and 32 and the heating elements 21 and 22 may also be easily thermally connected to one another if the radiating section 15 is formed of the single radiating member 71.

A portable computer 1 as an electronic apparatus according to a fourth embodiment of the invention will now be described with reference to FIG. 11. Like reference numbers are used to designate structures of the portable computers of the first and fourth embodiments having the same or similar functions, and a description of those structures is omitted.

As shown in FIG. 11, the portable computer 1 is provided with a third heating element 81, third heat pipe 82, third heat receiving member 83, and third pressing member 84. A heat radiating section 15 includes a third radiating member 85. The third heating element 81, like first and second heating elements 21 and 22, is a heating component that is mounted on a circuit board 14. The third heat pipe 82 includes a first end portion 82a thermally connected to the third heating element 81, a second end portion 82b thermally connected to the third radiating member 85, a first middle portion 82c thermally connected to the first heating element 21, and a second middle portion 82d thermally connected to the second heating element 22.

A heat conductive member 41 is provided between the first middle portion 82c and the first heating element 21. Another heat conductive member 41 is provided between the second middle portion 82d and the second heating element 22. The remaining configurations of the portable computer 1 other than those described above are the same as those of the first embodiment.

According to this arrangement, heat from the first and second heating elements 21 and 22 may be transported by a plurality of heat pipes 31, 32 and 82, and the heat transport capacity of the pipes may not be easily reduced even when the portable computer 1 is tilted, for example. Thus, a high cooling performance may be realized.

The third heat pipe 82 need not always be thermally connected to both the first and second heating elements 21 and 22, but may be thermally connected to only one of the heating elements.

Although the portable computers 1 according to the first to fourth embodiments of the present invention have been described herein, the invention is not limited to these embodiments. The structures according to the embodiments may be suitably combined in use. In the third and fourth embodiments, for example, the heat pipes 31, 32 and 82 may be directly thermally connected to the heating elements 21, 22 and 81 without using the heat receiving members 35, 36 and 83, as in the second embodiment.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing;
a circuit board contained in the housing;
a heat radiating section provided in the housing;
a first heating element mounted on the circuit board;
a second heating element mounted on the circuit board;
a first heat pipe including a first end portion thermally connected to the first heating element and a second end portion thermally connected to the heat radiating section;
a second heat pipe including a first end portion thermally connected to the second heating element, a second end portion thermally connected to the heat radiating section, and a middle portion opposed to the first heating element; and
a heat conductive member having flexibility and provided between the middle portion of the second heat pipe and the first heating element so as to thermally connect the middle portion of the second heat pipe to the first heating element.

2. An electronic apparatus according to claim 1, further comprising:
a pressing member which is opposed to the first end portion of the second heat pipe, presses the first end portion of the second heat pipe toward the second heating element, and presses the middle portion of the second heat pipe toward the heat conductive member.

3. An electronic apparatus according to claim 1, further comprising:
a pressing member which is opposed to the first end portion of the first heat pipe and presses the first end portion of the first heat pipe toward the first heating elements the pressing member having a gap between the second heat pipe.

4. An electronic apparatus according to claim 1, wherein the heat radiating section includes a first radiating member thermally connected to the first heat pipe and a second radiating member thermally connected to the second heat pipe, the first and second radiating members being independent of each other.

5. An electronic apparatus according to claim 1, further comprising:
a first heat receiving member opposed and thermally connected to the first heating element and thermally connected with the first end portion of the first heat pipe, and
a second heat receiving member opposed and thermally connected to the second heating element and thermally connected with the first end portion of the second heat pipe, and wherein
the heat conductive member is interposed between the middle portion of the second heat pipe and the first heat receiving member and thermally connects the middle portion of the second heat pipe to the first heat receiving member.

6. An electronic apparatus according to claim 5, further comprising:
a heat conductive grease which is spread between the first heating element and the first heat receiving member and between the second heating element and the second heat receiving member.

7. An electronic apparatus according to claim 5, wherein the first end portion of the first heat pipe is thermally connected to a central portion of the first heat receiving member, and the middle portion of the second heat pipe is thermally connected to a region off the central portion of the first heat receiving member.

8. An electronic apparatus according to claim 1, wherein the second heating element is larger in energy consumption than the first heating element.

9. An electronic apparatus according to claim 1, wherein the upper limit of a specification temperature of the first heating element is higher than that of the second heating element.
